(19) United States
(12) Patent Application Publication
(10) Pub. No.: US 2005/0145986 A1
(43) Pub. Date: Jul. 7, 2005

(54) Semiconductor device and method of fabricating the same

(76) Inventor: Kazutaka Akiyama, Matsudo-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 10/986,084

(22) Filed: Nov. 12, 2004

(30) Foreign Application Priority Data
Nov. 12, 2003 (JP) 2003-382747

(51) Int. Cl. H01L 21/8234; H01L 29/00

(52) U.S. Cl. 257/532; 438/957; 257/535

(57) ABSTRACT

A semiconductor device according to an aspect of this invention comprises a first lower interconnection formed on an insulating film on a semiconductor substrate, a first via formed on the first lower interconnection, and an MIM capacitor formed on the first via, and including a lower electrode, capacitor insulating film, and upper electrode.

### CROSS-REFERENCE TO RELATED APPLICATIONS

This application is based upon and claims the benefit of priority from prior Japanese Patent Application No. 2003-382747, filed Nov. 12, 2003, the entire contents of which are incorporated herein by reference.

### BACKGROUND OF THE INVENTION

1. Field of the Invention

The present invention relates to a semiconductor device and a method of fabricating the same.

2. Description of the Related Art

One of the conventional techniques of this type is a method of forming metal interconnections for electrically connecting elements formed on an Si wafer. For example, this method forms interconnections by patterning an Al film formed on an insulating film by photolithography, and removing Al in pattern space portions by anisotropic etching.

As micropatterning advances, however, it becomes difficult to form Al interconnections by anisotropic etching, and bury an insulating film in space portions between the Al interconnections. As a method of forming metal interconnections which replace Al interconnections, a method (to be referred to as Cu damascene wiring hereinafter) of forming trenches in an insulating film by patterning using anisotropic etching and burying Cu in these trenches is known.

Also, as a capacitor element which replaces a stacked structure of Si-insulating film-Si, a capacitor element (to be referred to as an MIM capacitor hereinafter) having a stacked structure of metal-insulating film-metal is known. Since this MIM capacitor uses a metal as an electrode, it is preferable to simultaneously form capacitor electrodes and interconnections between metal wiring layers.

The conventional MIM capacitor formation method uses dual damascene by which via holes for forming vias and trenches for forming interconnections are formed, and then Cu is buried to form upper interconnections. Another formation method uses single damascene by which after via holes are formed, Cu is buried in the via holes and removed from portions other than the via holes by CMP, an insulating film is formed, trenches are formed in this insulating film, and Cu is buried in the trenches and removed from portions other than the trenches, thereby forming upper interconnections. Dual damascene wiring is most frequently used because the number of steps is small. However, deep via holes must be initially formed in this dual damascene wiring, and this formation is difficult.

In the structure described above, a decrease in speed caused by coupling of signals propagating in lower and upper interconnections must be prevented by increasing the distance (height) between the lower and upper interconnections as large as possible. However, as micropatterning progresses, it becomes difficult to bury Cu in the dual damascene structure, so the distance between the lower and upper interconnections cannot be well increased. Therefore, single damascene wiring in which via holes and upper interconnections are separately formed is required in the future.

In this case, when an MIM capacitor is formed by the same method as above, it is necessary to planarize lower interconnections and an insulating film on the MIM capacitor by CMP, and separately form via holes as needed.

It is also effective to decrease the height of a projection of the insulating film on the MIM capacitor by decreasing the thickness of the MIM capacitor. However, the structure of the MIM capacitor limits the position of a via hole, which extends from the upper interconnection to the lower electrode, to a peripheral portion of the MIM capacitor where no upper electrode is formed. Accordingly, the sheet resistance of the lower electrode must be decreased so as not to produce any difference in resistance of the lower electrode between the peripheral portion and central portion of the MIM capacitor.

The lower interconnection can also be used as the lower electrode of the MIM capacitor. This method facilitates planarization because the height of the MIM capacitor decreases by the amount of lower electrode. However, the electrode of the MIM capacitor is generally as large as from a few μm to a few mm. When the lower interconnection is to be used as the lower electrode, therefore, Cu in the lower electrode is removed more than necessary to cause erosion when Cu buried in the trench is removed by CMP. In some cases, Cu is completely removed and unable to function as the lower electrode.

If the insulating film of the MIM capacitor is smaller than the lower electrode, Cu in the lower electrode may corrode when the insulating film is processed by etching. This can also occur in the whole lower interconnection other than the lower electrode. By contrast, if the insulating film of the MIM capacitor is larger than the lower electrode, the capacitor characteristics at the end portion of the lower electrode readily deteriorate. The cause of this deterioration is that in the boundary portion between a barrier metal (BM) and Cu in the lower electrode, Cu is readily dissolved and removed by CMP or by washing after CMP, and this makes the film thickness of the capacitor insulating film formed on the lower electrode nonuniform, or allows easy formation of pinholes.

### BRIEF SUMMARY OF THE INVENTION

A semiconductor device according to an aspect of the present invention comprises a first lower interconnection formed on an insulating film on a semiconductor substrate, a first via formed on the first lower interconnection, and an MIM capacitor formed on the first via, and including a lower electrode, capacitor insulating film, and upper electrode.

A semiconductor device fabrication method according to another aspect of the present invention comprises forming a first lower interconnection on an insulating film on a semiconductor substrate, forming a first via on the first lower interconnection, and forming, on the first via, an MIM capacitor including a lower electrode, capacitor insulating film, and upper electrode.

### BRIEF DESCRIPTION OF THE SEVERAL VIEWS OF THE DRAWING

FIGS. 1A and 1B are sectional views showing a method of forming an MIM capacitor of a semiconductor device according to the first embodiment;

FIGS. 2A, 2B, and 2C are sectional views showing the method of forming the MIM capacitor of the semiconductor device according to the first embodiment;

FIG. 3 is a plan view showing the arrangement of a plurality of MIM capacitors according to the first embodiment;

FIG. 4 is a sectional view of the MIM capacitor according to the first embodiment;

FIGS. 5A, 5B, and 5C are sectional views showing a method of forming an MIM capacitor of a semiconductor device according to the second embodiment;

FIGS. 6A, 6B, 6C, and 6D are sectional views showing a method of forming an MIM capacitor of a semiconductor device according to the first comparative example;

FIG. 7 is a sectional view of the MIM capacitor according to the first comparative example;

FIGS. 8A, 8B, 8C, and 8D are sectional views showing a method of forming an MIM capacitor of a semiconductor device according to the second comparative example;

FIGS. 9A, 9B, and 9C are sectional views showing a method of forming an MIM capacitor of a semiconductor device according to the third comparative example; and

FIGS. 10A, 10B, and 10C are sectional views showing the method of forming the MIM capacitor of the semiconductor device according to the third comparative example.

### DETAILED DESCRIPTION OF THE INVENTION

Embodiments of the present invention will be described below with reference to the accompanying drawing.

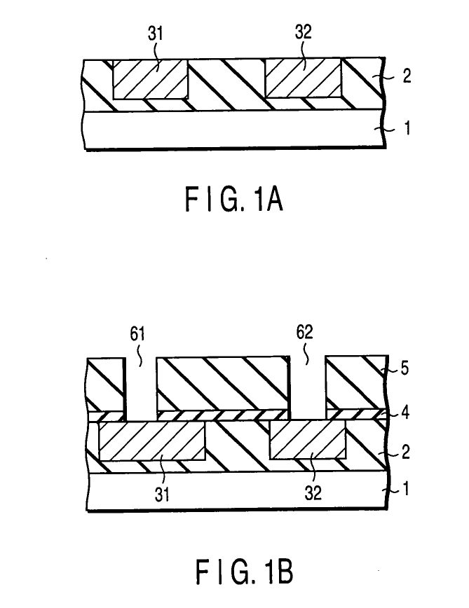

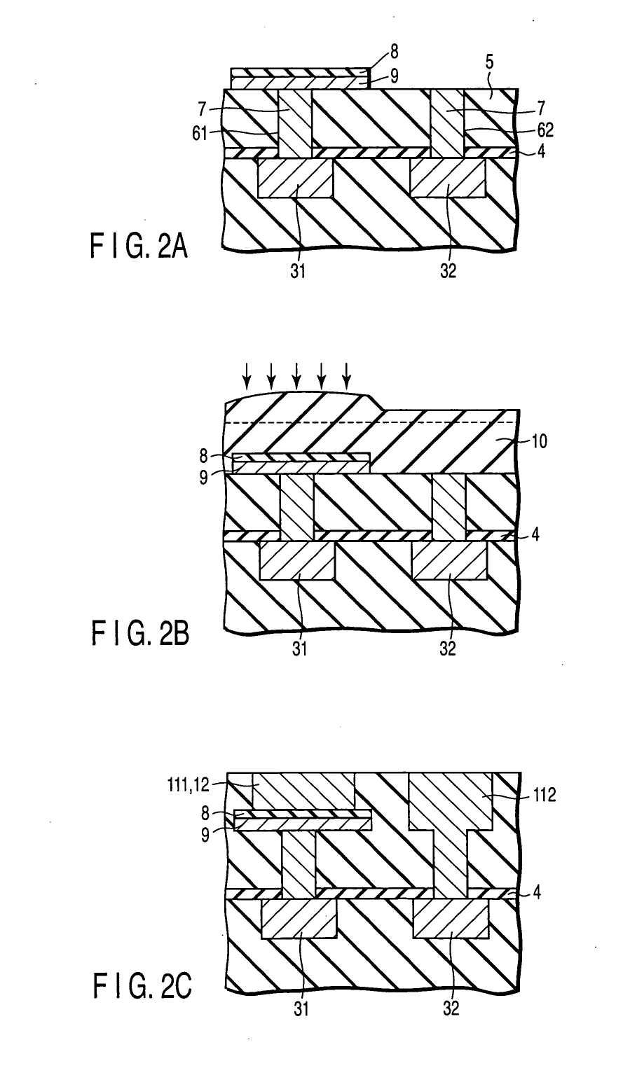

FIGS. 1A, 1B, 2A, 2B, and 2C are sectional views showing a method of forming an MIM capacitor of a semiconductor device according to the first embodiment. First, as shown in FIG. 1A, a 0.5-μm thick SiO₂ film 2 is formed on an Si substrate 1, a wiring portion is patterned by photoresist processing, and trenches are formed by anisotropic etching (to be referred to as RIE hereinafter) by using a CF-based gas. In addition, films of TaN and Cu are formed by PVD, and used as electrodes to bury Cu in the trenches by plating. The Cu and TaN films in portions other than the trenches are removed by CMP to form lower interconnections (first interconnections) 31 and 32.

As shown in FIG. 1B, a 0.1-μm thick SiN film 4 is formed so as not to expose Cu from the lower interconnections (first interconnections) 31 and 32. After that, a 0.3-μm thick SiO₂ film 5 is formed, patterned by photoresist processing, and processed by RIE using a CF-based gas, thereby simultaneously forming via holes 61 and 62 reaching the lower interconnections (first interconnections) 31 and 32, respectively. The diameter of the via holes 61 and 62 is 0.15 μm.

As shown in FIG. 2A, films of TaN and Cu are formed by PVD, and Cu 7 as vias is buried by plating. The Cu and TaN films in portions other than the via holes 61 and 62 are removed by CMP. A stacked film of TiN and SiN is formed thereon and patterned by photoresist processing, and an insulating film 8 of an MIM capacitor is formed by RIE using a CF-based gas. The stacked film is further patterned by photoresist processing, and a TiN lower electrode 9 is formed by RIE using a Cl-based gas.

The Cu surface of a via hole other than the via holes 61 and 62 may be slightly corroded by the Cl-based gas in some cases. However, this corroded portion can be removed by ammonium fluoride-based wet processing after TiN is processed.

As shown in FIG. 2B, a 0.3-μm thick SiO₂ film 10 is formed, and a projection of the SiO₂ film 10 in an MIM capacitor portion is planarized by CMP. The height of the projection of the SiO₂ film 10 in the MIM capacitor portion is 0.2 μm before CMP and 0.03 μm or less after that.

As shown in FIG. 2C, patterning is performed by photolithography, and trenches are formed in the SiO₂ film 10 by RIE using a CF-based gas. One of the trenches is formed on the insulating film 8 of the MIM capacitor. A margin (DOF) for focusing variations when the trenches are patterned by photolithography is 0.4 μm, and the trench on the MIM capacitor is also well patterned. The processing selectivity of the MIM capacitor insulating film 8 to the SiO₂ film 10 is 30, and the etching amount of the surface of the MIM capacitor insulating film 8 is 0.1 μm.

Furthermore, films of TaN and Cu are formed by PVD and used as electrodes to bury Cu in the trenches by plating. Then, the Cu and TaN films in portions other than the trenches are removed by CMP, thereby simultaneously forming upper interconnections (second interconnections) 111 and 112 and an upper electrode 12 of the MIM capacitor.

In this structure, the trench other than the one on the MIM capacitor may also be formed on the via hole. A corroded portion on the Cu surface has no problem, and an electrical contact can be obtained on the via hole when the upper interconnections (second interconnections) are formed.

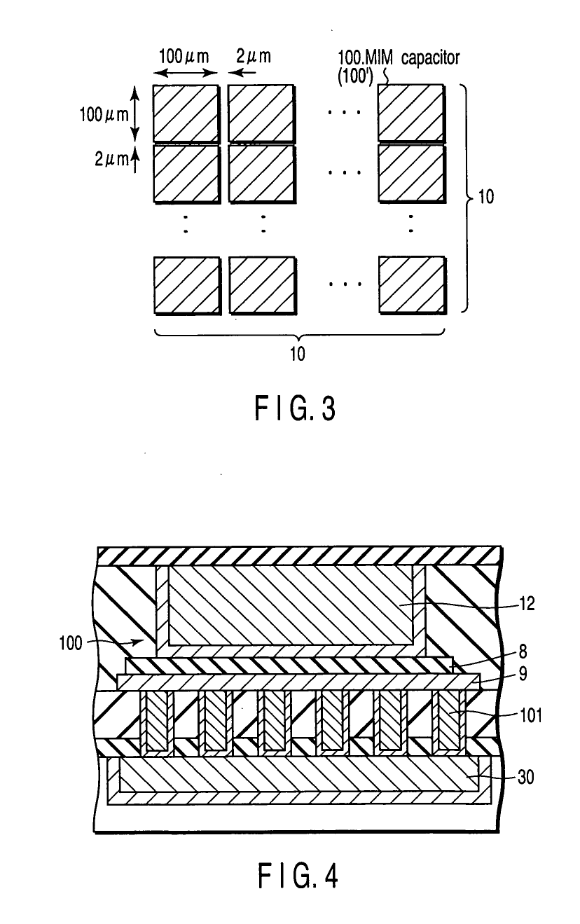

FIG. 3 is a plan view showing the arrangement of a plurality of MIM capacitors. Referring to FIG. 3, 10×10=100 MIM capacitors 100 formed as described above are arranged. Each MIM capacitor 100 has a square shape of 100 μm side, and a spacing of 2 μm is formed between adjacent MIM capacitors 100. The film thickness of the MIM capacitor 100 is 0.2 μm as a total film thickness of the upper electrode 12, lower electrode 9, and insulating film 8. The thickness of the lower electrode 9 is 0.1 μm.

The characteristics of the MIM capacitor formed as described above had no problem, and the resistance of the upper electrode is stably low. Also, as indicated by a sectional view of an MIM capacitor shown in FIG. 4, when a plurality of via holes 101 are equally spaced at a pitch of 0.3 μm in the longitudinal direction and lateral direction below the MIM capacitor 100, the resistance of the lower electrode is also stably low.

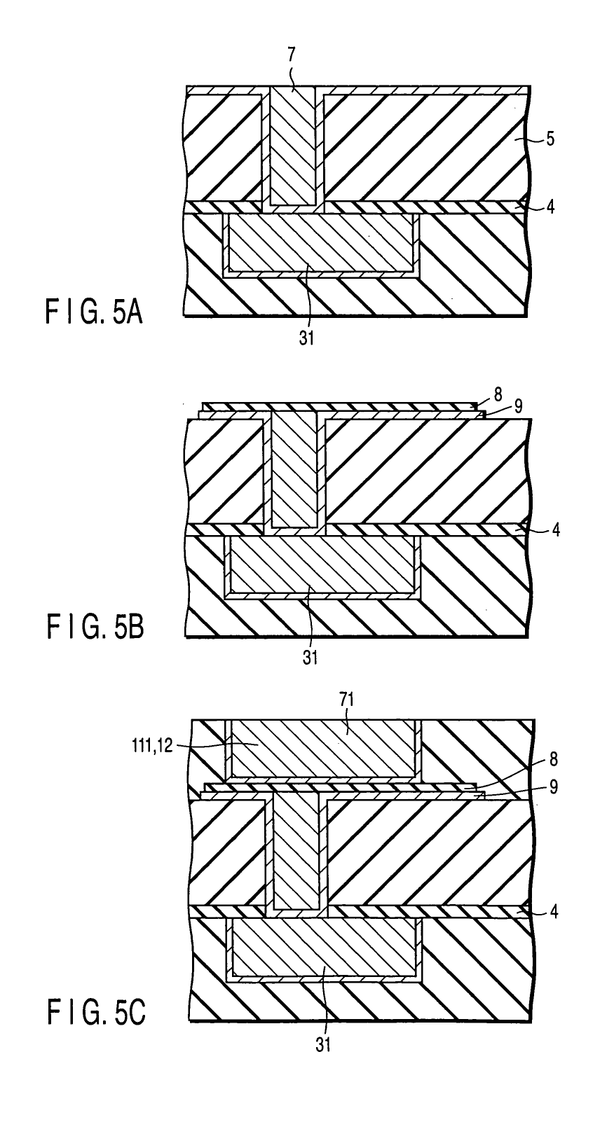

FIGS. 5A, 5B, and 5C are sectional views showing a method of forming an MIM capacitor of a semiconductor device according to the second embodiment. As shown in FIG. 1A, lower interconnections (first interconnections 31 and 32 are formed in the same manner as in the first embodiment. As shown in FIG. 1B, via holes 61 and 62 reaching the lower interconnections (first interconnections) 31 and 32, respectively, are formed.

After that, as shown in FIG. 5A, films of TaN and Cu are formed by PVD, and Cu 7 as vias is buried in the via holes 61 and 62 by plating. In addition, Cu in portions other than the via holes is removed by CMP without removing any TaN. In this CMP for removing Cu, the selectivity of TaN to Cu is 100 or more, so TaN is hardly etched but left behind as a barrier metal.

As shown in FIG. 5B, an SiN film as a capacitor insulating film is formed and patterned by photoresist processing, and an insulating film 8 of an MIM capacitor is formed by RIE using a CF-based gas. Furthermore, as shown in FIG. 2A, patterning is performed by photoresist processing, and a TaN lower electrode 9 is formed by RIE using a Cl-based gas. A margin (DOF) for focusing variations when the trenches are patterned by photolithography is 0.3 μm, so the trench on the MIM capacitor is also well patterned.

In this case, the Cu surface of the via hole other than the MIM capacitor portion may be slightly corroded by the Cl-based gas in some cases. However, this corroded portion can be removed by ammonium fluoride-based wet processing after TiN is processed.

As shown in FIG. 2B, a 0.3-μm thick SiO₂ film 10 is formed, and a projection of the SiO₂ film 10 in the MIM capacitor portion is planarized by CMP. The height of the projection of the SiO₂ film 10 in the MIM capacitor portion is 0.2 μm before CMP and 0.03 μm or less after that.

After that, as shown in FIG. 5C, patterning is performed by photolithography, and a trench is formed in the SiO₂ film 10 by RIE using a CF-based gas. This trench is also formed on the insulating film 8 of the MIM capacitor. The processing selectivity of the MIM capacitor insulating film 8 to the SiO₂ film 10 is 30, and the etching amount of the surface of the MIM capacitor insulating film 8 is 0.1 μm.

Furthermore, films of TaN as a barrier metal and Cu are formed in the trench by PVD and used as electrodes to bury Cu 71 in the trench by plating. Then, the Cu and TaN films in portions other than the trench are removed by CMP, thereby simultaneously forming an upper interconnection (second interconnection) 111 and an upper electrode 12 of the MIM capacitor.

The characteristics of the MIM capacitor formed as described above had no problem, and the resistance of the upper electrode is stably low. The resistance of the lower electrode of the MIM capacitor is also stably low because not only a plurality of via holes are equally spaced at a pitch of 0.3 μm in the longitudinal direction and lateral direction below the lower electrode as shown in FIG. 4, but also the barrier metal in the via hole and the lower electrode are integrated.

In this structure, the trench other than the one on the MIM capacitor may also be formed on the via hole. A corroded portion on the Cu surface has no problem, and an electrical contact can be obtained on the via hole when the upper interconnection (second interconnection) is formed.

Also, if the resistance is not sufficiently increased by the film thickness of the barrier metal of the via hole, a TiN film may also be formed as in the first embodiment on TaN left behind after Cu in portions other than the via hole is removed by CMP. Even in this case, the via hole and at least a portion of the lower electrode are integrated by TaN as the barrier metal. This effectively facilitates stabilization of the resistance of the lower electrode.

Note that the upper interconnection (second interconnection) 111 and the upper electrode 12 of the MIN capacitor may also be formed by forming a conductor on the insulating film 8 of the MIM capacitor, patterning the conductor, and processing the conductor by using RIE.

Comparative examples of the above embodiments will be described below.

### FIRST COMPARATIVE EXAMPLE

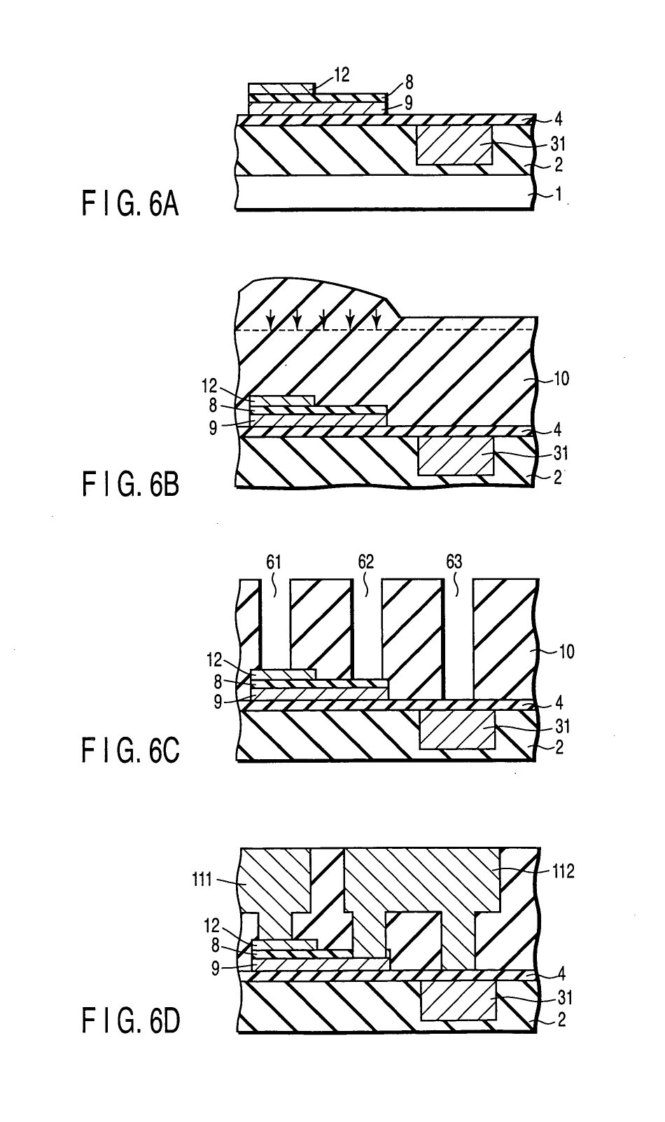

FIGS. 6A, 6B, 6C, and 6D are sectional views showing a method of forming an MIM capacitor of a semiconductor device according to the first comparative example. First, as shown in FIG. 6A, a 0.5-μm thick SiO₂ film 2 is formed on an Si substrate 1, a wiring portion is patterned by photoresist processing, and a trench is formed by anisotropic etching (to be referred to as RIE hereinafter) by using a CF-based gas. In addition, films of TaN and Cu are formed by PVD, and used as electrodes to bury Cu in the trench by plating. The Cu and TaN films in portions other than the trench are removed by CMP to form a lower interconnection (first interconnection) 31.

A 0.1-μm thick SiN film 4 is then formed so as not to expose Cu from the lower interconnection (first interconnection) 31. After that, a stacked film of TiN, SiN, and TiN is formed and patterned by photoresist processing, and an upper electrode 12 of an MIM capacitor is formed by RIE using a Cl-based gas. In addition, patterning is performed by photoresist processing, and an insulating film 8 of the MIM capacitor is formed by RIE using a CF-based gas. Furthermore, patterning is performed by photoresist processing, and a TiN lower electrode 9 is formed by RIE using a Cl-based gas.

As shown in FIG. 6B, a 0.6-μm thick SiO₂ film 10 is formed, and a projection of the SiO₂ film 10 in an MIM capacitor portion is planarized by CMP. The height of the projection of the SiO₂ film 10 in the MIM capacitor portion is 0.4 μm before CMP and 0.06 μm or less after that.

As shown in FIG. 6C, patterning is performed by photoresist processing, and a via hole 63 reaching the lower interconnection (first interconnection) 31 is formed by RIE using a CF-based gas. The diameter of this via hole is 0.15 μm. A margin (DOF) for focusing variations when the photoresist is patterned is as small as 0.15 μm, and this made patterning of some via holes impossible. Therefore, as shown in FIG. 6C, it is necessary to separately pattern via holes 61 and 62 on the MIM capacitor and the via hole 63 on the lower interconnection (first interconnection 1) 31.

Also, when the via holes are formed, TiN in the upper electrode 12 is etched because the depth of the via hole 63 on the lower interconnection (first interconnection) 31 is different from that of the via hole 62 on the lower electrode 9 and that of the via hole 61 on the upper electrode 12. The selectivity of TiN to SiO₂ is 60, and the etching amount of TiN is 0.01 μm. However, since the film thickness of the upper electrode 12 is originally as small as 0.05 μm, pinholes in TiN could be fatal defects.

After that, as shown in FIG. 6D, patterning is performed by photolithography, and trenches are formed by RIE using a CF-based gas. In this state, one of the trenches is formed on the insulating film 8 of the MIM capacitor. A margin (DOF) for focusing variations when these trenches are patterned by photolithography is 0.3 μm, so the trench on the MIM capacitor is also well patterned. However, the DOF is obviously lower than those of the first and second embodiments.

Furthermore, films of TaN and Cu are formed by PVD and used as electrodes to bury Cu in the trenches by plating. Then, the Cu and TaN films in portions other than the trenches are removed by CMP, thereby forming upper interconnections (second interconnections) 111 and 112.

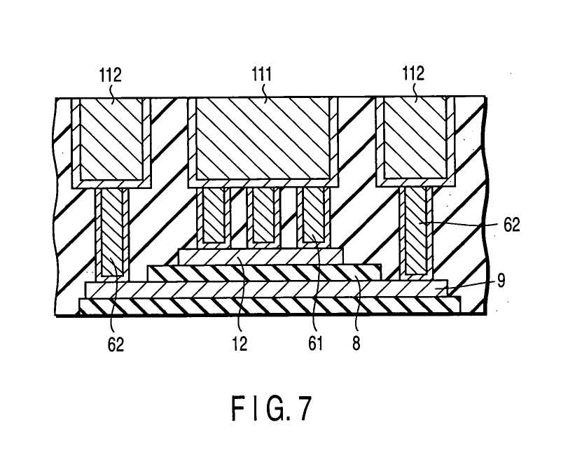

The film thickness of the MIM capacitor described above is larger than those of the MIM capacitors in the first and second embodiments for the reason explained below. As shown in FIG. 7, the via hole 62 from the upper interconnection (second interconnection) 112 to the lower electrode 9 is limitedly formed only on the peripheral portion of the MIM capacitor where the upper electrode 12 is not formed. Therefore, it is necessary to lower the sheet resistance of the lower electrode 9 so as not to produce any difference in resistance of the lower electrode 9 between the peripheral portion and central portion of the MIM capacitor. The thickness of the lower electrode 9 is 0.3 μm.

10×10=100 MIM capacitors formed as described above are arranged as shown in FIG. 3. Each MIM capacitor 100′ had a square shape of 100 μm side, and a spacing of 2 μm is formed between adjacent MIM capacitors 100′. The film thickness of the MIM capacitor 100′ is 0.4 μm as a total film thickness of the upper electrode 12, lower electrode 9, and insulating film 8.

The characteristics of the MIM capacitor formed as described above had no problem, and the resistance of the upper electrode is stably low. However, when the film thickness of the lower electrode is changed to 0.1 μm as in the first and second embodiments, a potential difference is produced between the peripheral portion and central portion of the MIM capacitor. As a consequence, the capacitor characteristics deteriorated.

### SECOND COMPARATIVE EXAMPLE

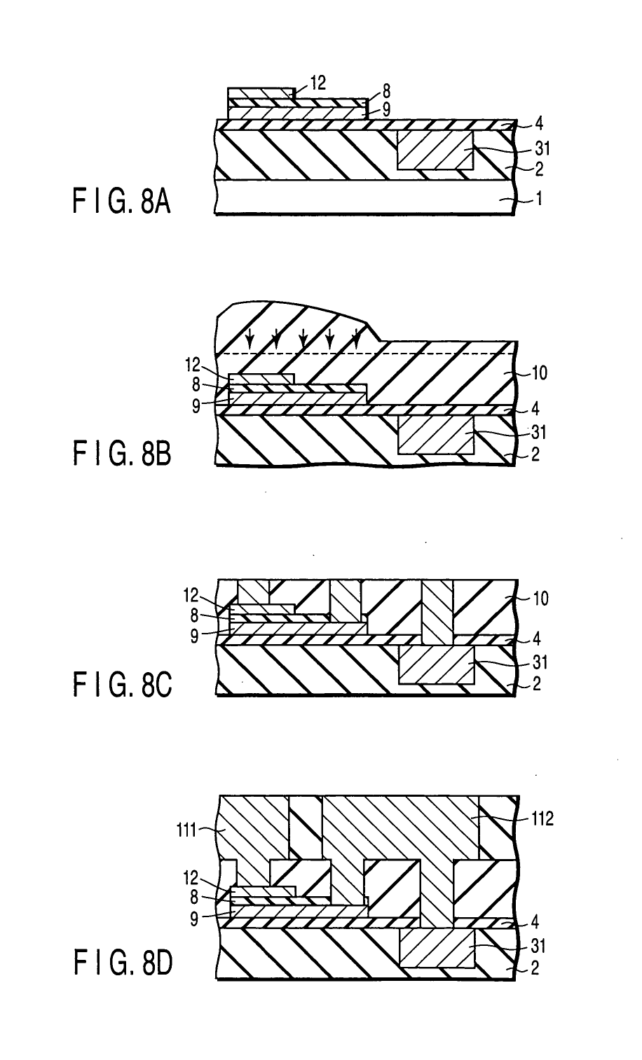

FIGS. 8A, 8B, 8C, and 8D are sectional views showing a method of forming an MIM capacitor of a semiconductor device according to the second comparative example. As shown in FIG. 8A, after a lower interconnection (first interconnection) 31 is formed, an SiN film 4 is formed, and an MIM capacitor is formed on the SiN film 4, following the same procedure as in the first comparative example.

As shown in FIG. 8B, a 0.3-μm thick SiO₂ film 10 is formed, and a projection of the SiO₂ film 10 is planarized by CMP. As shown in FIG. 8C, via holes are formed by patterning and RIE. As in the first comparative example, however, the DOF is as low as 0.15 μm, and this made it difficult to simultaneously pattern portions on the MIM capacitor and lower interconnection (first interconnection) 31.

As shown in FIG. 8D, upper interconnections (second interconnections) 111 and 112 are formed, and the MIM capacitor characteristics are checked. Consequently, when the film thickness of the lower electrode is 0.1 μm as in the first and second embodiments, a potential difference is produced between the peripheral portion and central portion of the MIM capacitor, and the characteristics deteriorated.

### THIRD COMPARATIVE EXAMPLE

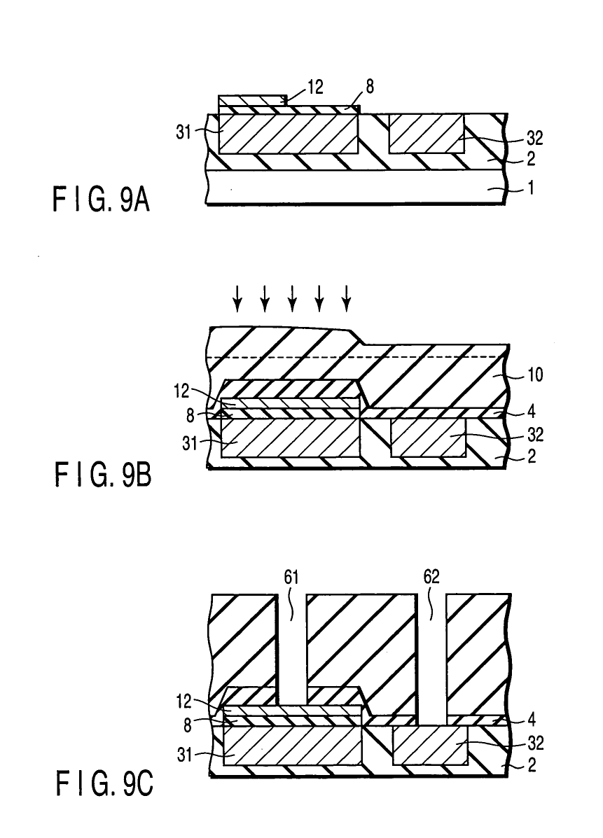

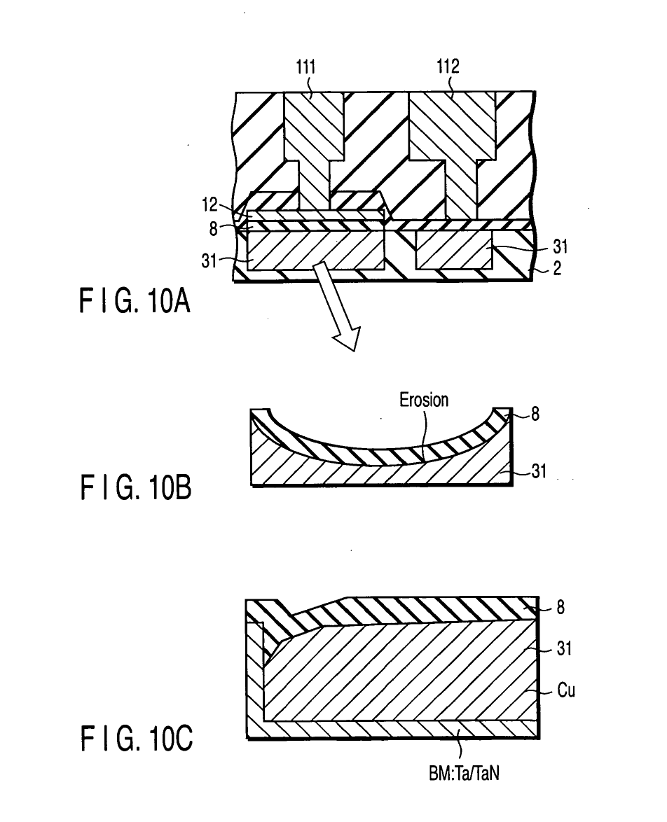

FIGS. 9A, 9B, 9C, 10A, 10B, and 10C are sectional views showing a method of forming an MIM capacitor of a semiconductor device according to the third comparative example. As shown in FIG. 9A, after lower interconnections (first interconnections) 31 and 32 are formed, an insulating film 8 for an MIM capacitor and a TiN film for an upper electrode 12 are immediately formed, and processed by patterning and RIE, thereby forming an MIM capacitor.

As shown in FIG. 9B, an SiO₂ film 10 is formed, and a projection of the SiO₂ film 10 is planarized by CMP. As shown in FIG. 9C, via holes 61 and 62 are formed by patterning and RIE. As shown in FIG. 10A, upper interconnections (second interconnections) 111 and 112 are formed.

Unfortunately, CF- and Cl-based gases used when the MIM capacitor is formed in a portion of the lower interconnection (first interconnection) 31 caused corrosion, and this caused an open defect or a high resistance in the lower interconnection (first interconnection) 31.

Also, although the thickness of the lower interconnection (first interconnection) 31 is 0.3 μm, the lower interconnection (first interconnection) 31 in a portion serving as the lower electrode of the MIM capacitor has a size of 100 μm×100 μm. Therefore, as shown in FIG. 10B, erosion caused by Cu-CMP decreases the thickness of the residual Cu film to 0.1 μm in the central portion of the MIM capacitor. To prevent this, each side of the lower interconnection (first interconnection) 31 must be 5 μm or less. This imposes large limitations on the design rule of the MIM capacitor.

As shown in FIG. 10C, the MIM capacitor insulating film (SiN) 8 on the lower interconnection (first interconnection) 31 could not be well formed because Cu in the end portion of the lower interconnection (first interconnection) 31 is locally etched. As a consequence, cracks formed, and the breakdown voltage of the capacitor decreased.

In the embodiments as described above, lower interconnections (first interconnections) are formed (FIG. 1A), and via holes are formed below upper interconnections (second interconnections) and a lower electrode of an MIM capacitor (FIG. 1B). After that, films of a barrier metal (BM) and Cu are formed by PVD, and Cu is plated and buried in the via holes. Cu in portions other than the via holes is removed by CMP. In this state, by stopping CMP on the BM, the BM remaining in a field portion other than the via holes can be used as the lower electrode or as a part of the lower electrode of the MIM capacitor. Then, an MIM capacitor insulating film is formed on the lower electrode, and an MIM capacitor portion is formed by patterning (FIG. 2A).

In addition, an insulating film is formed, and trenches serving as upper interconnections (second interconnections) are formed (FIG. 2B). Although a trench is simultaneously formed in an upper electrode portion of an MIM capacitor, the insulating film of the MIM capacitor is not lost because the processing is performed under the conditions that the selectivity to the MIM capacitor insulating film is high. After that, films of BM and Cu are formed by PVD, Cu is buried by plating, and Cu in portions other than the trenches serving as upper interconnections (second interconnections) is removed by CMP, thereby forming upper interconnections (second interconnections) (FIG. 2C).

When the lower electrode of the MIM capacitor is formed on the via, the barrier metal for burying Cu in the via hole may also be used as the lower electrode or as a part of the lower electrode. In addition, since the upper interconnection (second interconnection) is also used as the upper electrode, the MIM capacitor can be formed simultaneously with the formation of the vias and upper interconnections (second interconnections). This shortens the fabrication process, and also facilitates planarization of the insulating film on the MIM capacitor. Furthermore, no large lower interconnections (first interconnections) need be formed even for a large MIM capacitor, and erosion caused by CMP of Cu is of no problem.

The resistance of the lower electrode is also stabilized at a low value by arranging a large number of vias in a matrix manner below the MIM capacitor (FIG. 4). Accordingly, the film thickness of the lower electrode can be made smaller than that of any conventional electrode. This makes it possible to further decrease the height of the projection of the SiO₂ film on the MIM capacitor.

The embodiments of the present invention can provide a semiconductor device and a method of fabricating the same by which an MIM capacitor can be easily formed, and the resistance of a lower electrode can be stabilized at a low value.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising:
a first lower interconnection formed on an insulating film on a semiconductor substrate;
a first via formed on the first lower interconnection; and
an MIM capacitor formed on the first via, and including a lower electrode, capacitor insulating film, and upper electrode.

2. The device according to claim 1, which further comprises a first upper interconnection formed on the MIM capacitor, and
wherein the upper electrode of the MIM capacitor is formed as a part of the first upper interconnection.

3. The device according to claim 1, further comprising:
a second lower interconnection formed on the insulating film on the semiconductor substrate;
a second via formed on the second lower interconnection; and
a second upper interconnection formed on the second via.

4. The device according to claim 2, further comprising:
a second lower interconnection formed on the insulating film on the semiconductor substrate;
a second via formed on the second lower interconnection; and
a second upper interconnection formed on the second via.

5. The device according to claim 1, wherein the first via is made up of at least a first conductor and a second conductor as a barrier metal of the first conductor, and the first via and at least a part of the lower electrode of the MIM capacitor are integrated by using the second conductor.

6. The device according to claim 2, wherein the first via is made up of at least a first conductor and a second conductor as a barrier metal of the first conductor, and the first via and at least a part of the lower electrode of the MIM capacitor are integrated by using the second conductor.

7. The device according to claim 3, wherein the first via is made up of at least a first conductor and a second conductor as a barrier metal of the first conductor, and the first via and at least a part of the lower electrode of the MIM capacitor are integrated by using the second conductor.

8. A semiconductor device fabrication method comprising:
forming a first lower interconnection on an insulating film on a semiconductor substrate;
forming a first via on the first lower interconnection; and
forming, on the first via, an MIM capacitor including a lower electrode, capacitor insulating film, and upper electrode.

9. The method according to claim 8, further comprising forming a first upper interconnection on the MIM capacitor.

10. The method according to claim 9, further comprising forming an upper electrode of the MIM capacitor as a part of the first upper interconnection.

11. The method according to claim 8, further comprising:
forming a second lower interconnection on the insulating film on the semiconductor substrate;
forming a second via on the second lower interconnection; and
forming a second upper interconnection on the second via.

12. The method according to claim 9, further comprising:
forming a second lower interconnection on the insulating film on the semiconductor substrate;
forming a second via on the second lower interconnection; and
forming a second upper interconnection on the second via.

13. The method according to claim 8, wherein the first via is made up of at least a first conductor and a second conductor as a barrier metal of the first conductor, and the first via and at least a part of the lower electrode of the MIM capacitor are integrated by using the second conductor.

14. The method according to claim 9, wherein the first via is made up of at least a first conductor and a second conductor as a barrier metal of the first conductor, and the first via and at least a part of the lower electrode of the MIM capacitor are integrated by using the second conductor.

15. The method according to claim 11, wherein the first and second vias are simultaneously formed.

16. The method according to claim 13, wherein the first and second vias are simultaneously formed.

17. The method according to claim 9, wherein the first upper interconnection and the upper electrode of the MIM capacitor are formed by forming an insulating film on the insulating film of the MIM capacitor, forming a trench in the insulating film, forming a third conductor and a fourth conductor as a barrier metal of the third conductor in the trench, and removing the third and fourth conductors in a portion other than the trench by CMP.

18. The method according to claim 10, wherein the first upper interconnection and the upper electrode of the MIM capacitor are formed by forming an insulating film on the insulating film of the MIM capacitor, forming a trench in the insulating film, forming a third conductor and a fourth conductor as a barrier metal of the third conductor in the trench, and removing the third and fourth conductors in a portion other than the trench by CMP.

19. The method according to claim 9, wherein the first upper interconnection and the upper electrode of the MIM capacitor are formed by forming a conductor on the insulating film of the MIM capacitor, and processing the conductor by using RIE.

20. The method according to claim 10, wherein the first upper interconnection and the upper electrode of the MIM capacitor are formed by forming a conductor on the insulating film of the MIM capacitor, and processing the conductor by using RIE.
